(19) United States
(12) Patent Application Publication
(10) Pub. No.: US 2008/0206944 A1
(43) Pub. Date: Aug. 28, 2008

(54) Method for fabricating trench DMOS transistors and schottky elements

(75) Inventors: Chiao-Shun Chuang, Kaohsiung (TW); Hung-Ta Weng, Taipei (TW)

Correspondence Address: BACON & THOMAS, PLLC, 625 SLATERS LANE, FOURTH FLOOR, ALEXANDRIA, VA, 22314, US

(73) Assignee: PAN-JIT INTERNATIONAL INC., KANG-SHAN TOWN (TW)

(21) Appl. No.: 11/709,715

(22) Filed: Feb. 23, 2007

(51) Int. Cl. H01L 21/8234

(52) U.S. Cl. 438/237; 257/E21.616

(57) ABSTRACT

A method uses simplified processes to complete the forming of the trench DMOS transistors and Schottky contacts. In the processes, only four masks, i.e. a trench pattern mask, a contact-hole pattern mask, a P+ contact pattern mask and a conductive-wire pattern mask, are applied to create desired trench DMOS transistors. In addition to the trench DMOS transistors, a Schottky contact is simultaneously formed at a junction between a conductive layer and a doped body region in the trench DMOS transistors without additional photolithography process.

### BACKGROUND OF THE INVENTION

1. Field of the Invention

The present invention relates to a method for fabricating trench double diffused metal oxide semiconductor (DMOS) transistors and Schottky elements, and more particularly to a method that uses simplified processes to form DMOS and Schottky elements.

2. Description of the Prior Arts

A double diffused metal oxide semiconductor (DMOS) transistor is typically employed as the power transistor for high voltage power integrated circuits. With a conventional process, six or seven different masks are generally used in the fabrication of the DMOS transistors.

With reference to FIG. 2A, an N-type epitaxial layer (301) is initially grown on an N+ doped substrate (300). An initial oxide layer (302) is subsequent grown on the epitaxial layer (301). A first photoresist layer (401) is then coated on the initial oxide layer (302) and a first mask (not shown) is used to define patterns of the first photoresist layer (401). Subsequently, an etching procedure is used to remove a part of the initial oxide layer (302) uncovered by the patterned first photoresist layer (401). The remaining first photoresist layer (401) is stripped from the initial oxide layer (302).

With reference to FIG. 2B, the epitaxial layer (301) not covered by the oxide layer (302) is implanted and diffused to form a P-body region (303). With reference to FIG. 2C, a second oxide layer (304) is deposited on the P-body region (304) and the initial oxide layer (302) through a chemical vapor deposition (CVD) procedure.

With reference to FIGS. 2D and 2E a second photoresist layer (402) is coated on the second oxide layer (402) and then a second mask (not shown) is used to define patterns of the second photoresist layer (402). The patterned second photoresist layer (402) is used as an etching mask to form multiple trenches (305) through the P-body region (303) and into the N-type epitaxial layer (301).

With reference to FIG. 2F after forming the trenches (305), the second photoresist layer (402) is removed. A gate oxide layer (306) is grown on the surfaces of the trenches (305) and the P-body region (303) where not covered by the first oxide layer (302). A polysilicon layer (307) is deposited by CVD process to fill the trenches (305) and cover the first oxide layer (302). After deposition of the polysilicon layer (307), a third photoresist layer (403) is coated on the polysilicon layer (307). A third mask (not shown) is used to pattern the third photoresist layer (403).

With reference to FIG. 2G an etching process is applied to remove the polysilicon layer (307) uncovered by the third photoresist layer (403) and to obtain a desired thickness of the polysilicon layer (307) within the trenches (305). After the etching process, the third photoresist layer (403) is stripped from the polysilicon layer (307).

With reference to FIG. 2H, a fourth photoresist layer (404) is coated on the structure shown in FIG. 2G. A fourth mask (not shown) is applied to pattern the fourth photoresist layer (404). The patterned fourth photoresist layer (404) is used as an etching mask for a subsequent implanting procedure. The P-body region (303) uncovered by the fourth photoresist layer (404) is implanted with N+ semiconductor material to form N+ doped regions (308). The N+ doped regions (308) are near the top surface of the P-body region (303) and abut to the gate oxide layer (306). After the implanting procedure, the fourth photoresist layer (404) and the remaining gate oxide layer (306) on the P-body region (303) are then removed.

With reference to FIG. 2I, a passivation layer (309) such as borophosphosilicate glass (BPSG) is grown on the polysilicon layer (307) and the P-body region (303). A fifth photoresist layer (405) is coated on the passivation layer (309) and defined to form patterns by a fifth mask (not shown).

With reference to FIG. 2J, the patterned fifth photoresist layer (405) is served as an etching mask when the passivation layer (309) is etched to form multiple contact holes (310). After the etching procedure of the passivation layer (309), the fifth photoresist layer (405) is removed to show the remaining passivation layer (309). The P-body region (303) exposed in the contact holes (310) are implanted to form P+ contact regions (311).

With reference to FIG. 2K, a conductive layer (312) is formed on the structure and fills the contact holes (310). Next, a sixth photoresist layer (406) is coated on the conductive layer (312) and defined by a sixth mask (not shown) to create desired patterns. The non-patterned regions of the conductive layer (312) is etched to expose a part of the passivation layer (309).

According to the foregoing discussion, the conventional method for fabrication of the DMOS transistors needs a great number of masks as shown in FIGS. 2A, 2C, 2F, 2H, 21, 2J and 2K. As the number of the photo masks raises, it is expectable that time, complexity and cost for manufacturing the semiconductor devices will be accordingly increased and unfavorable to obtain a satisfied production yield.

To overcome the shortcomings, the present invention provides a method for fabricating trench DMOS transistors and Schottky elements to mitigate or obviate the aforementioned problems.

### SUMMARY OF THE INVENTION

The objective of the present invention is to provide a method that fabricates the trench double diffused metal oxide semiconductor (DMOS) transistors and Schottky elements simply by using only four masks to reduce cost in fabricating processes and obtain a superior production yield.

The four masks are respectively used to define trench patterns, contact hole patterns, doped contact patterns and conductive-wire pattern. When forming the trench DMOS transistors, a Schottky contact as a Schottky diode can be simultaneously formed in the DMOS transistors.

Other objectives, advantages and novel features of the invention will become more apparent from the following detailed description when taken in conjunction with the accompanying drawings.

### BRIEF DESCRIPTION OF THE DRAWINGS

FIGS. 1A to 1H show a method for fabricating trench DMOS transistors and Schottky elements in accordance with the present invention; and

FIGS. 2A to 2K show a conventional method for fabricating trench DMOS transistors.

### DETAILED DESCRIPTION OF THE PREFERRED EMBODIMENTS

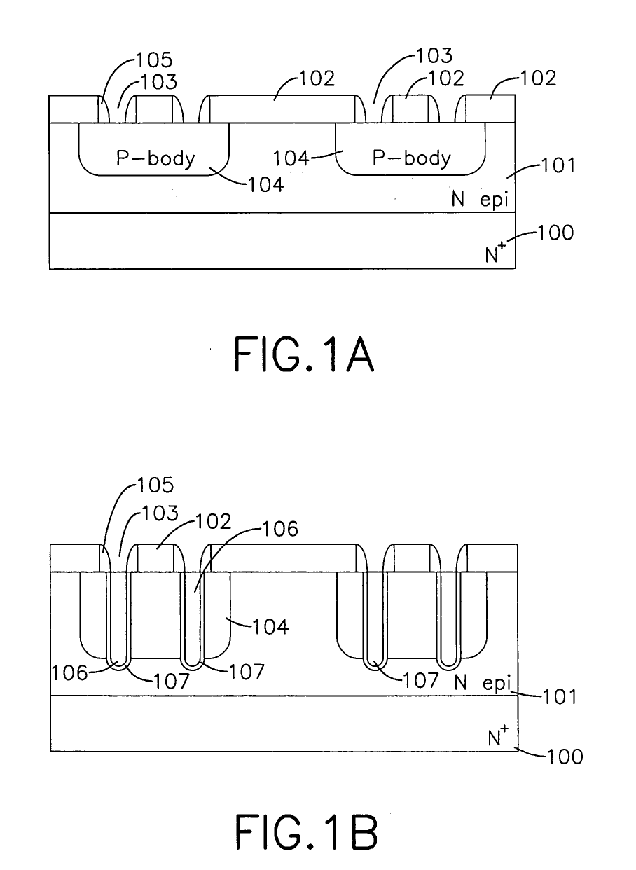

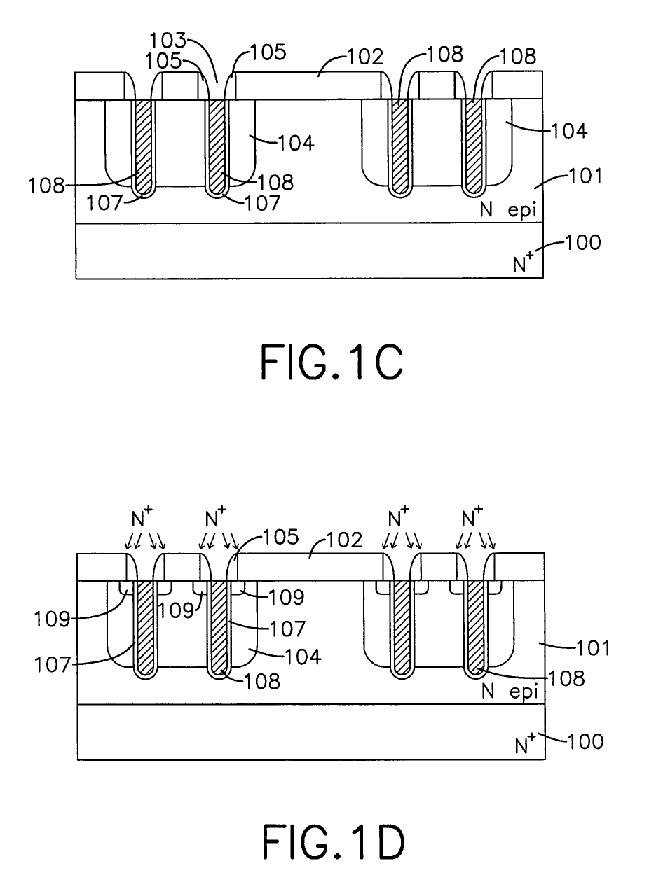

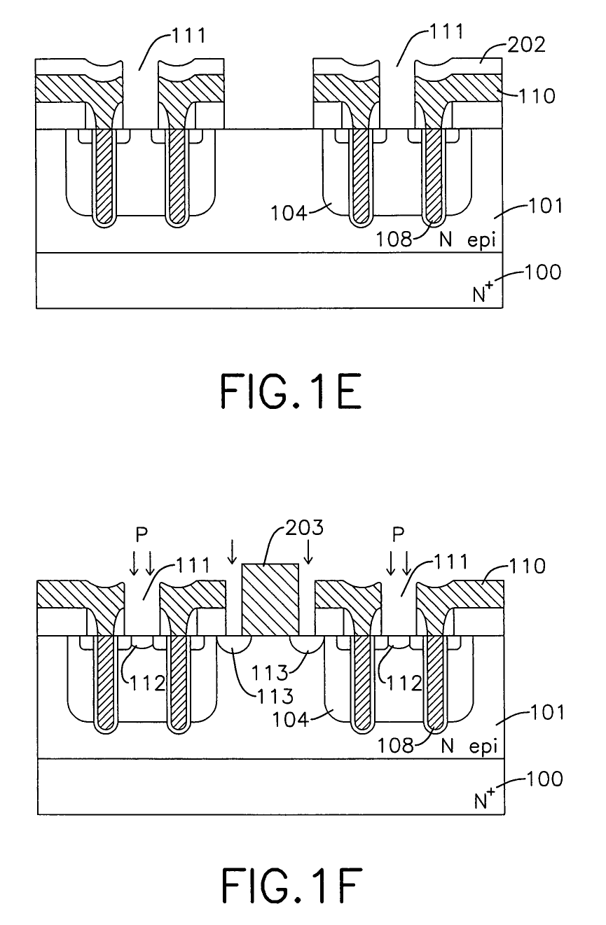

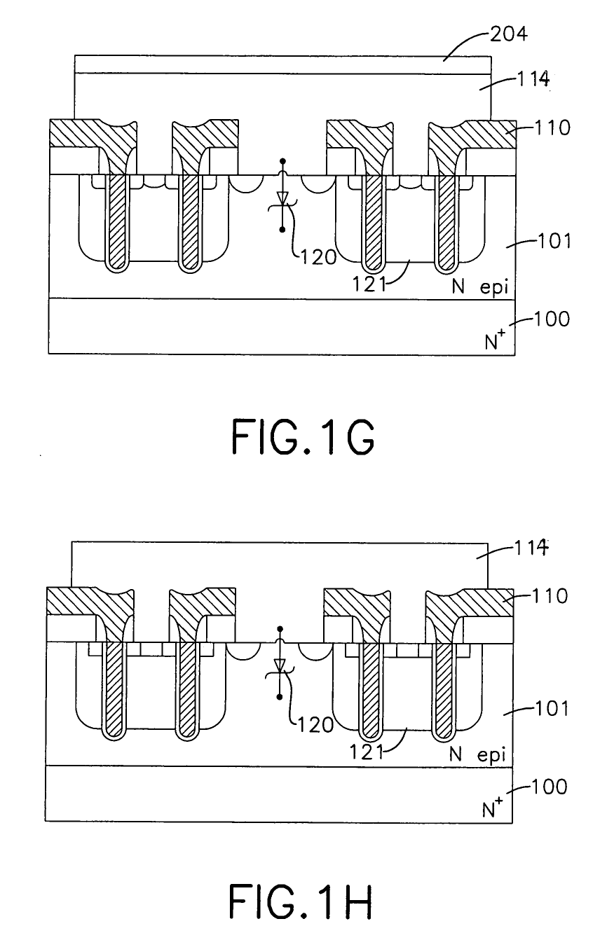

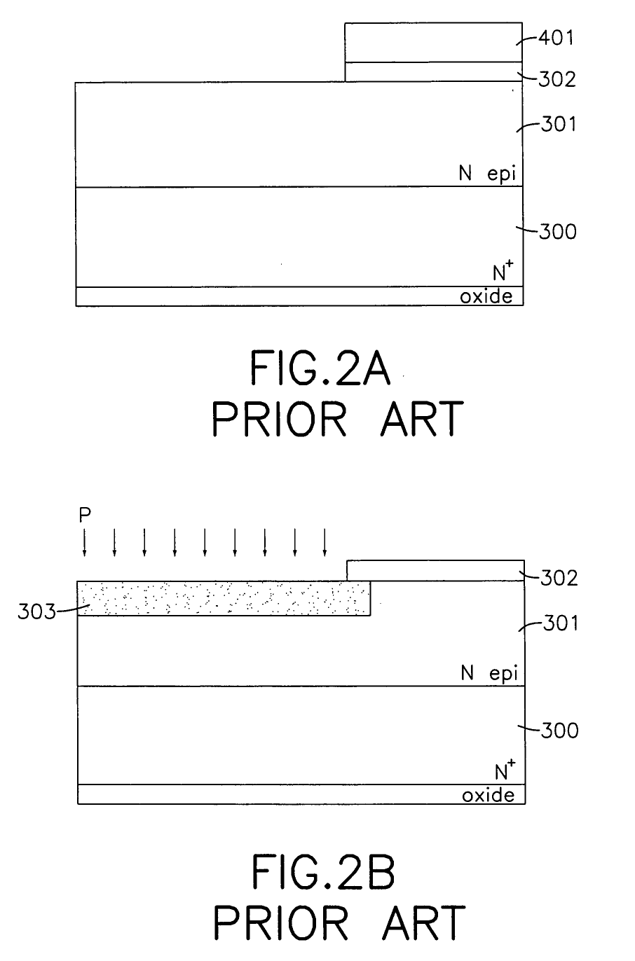

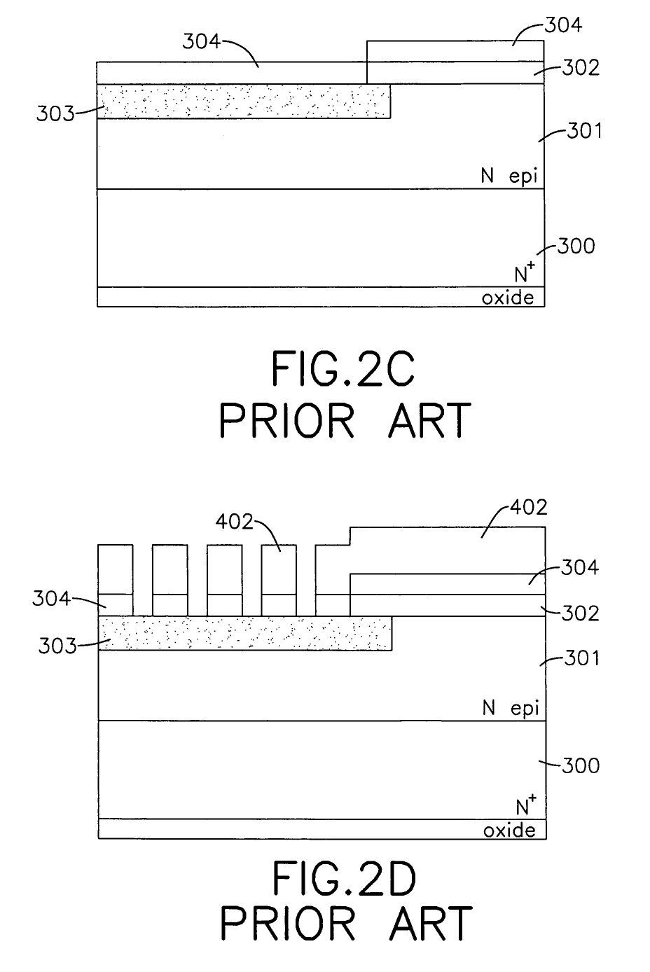

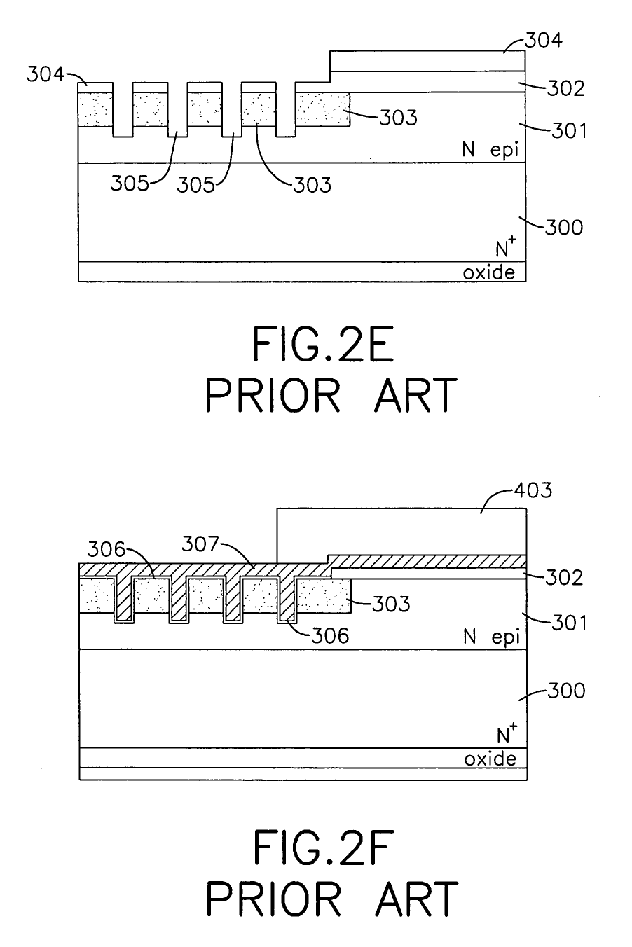

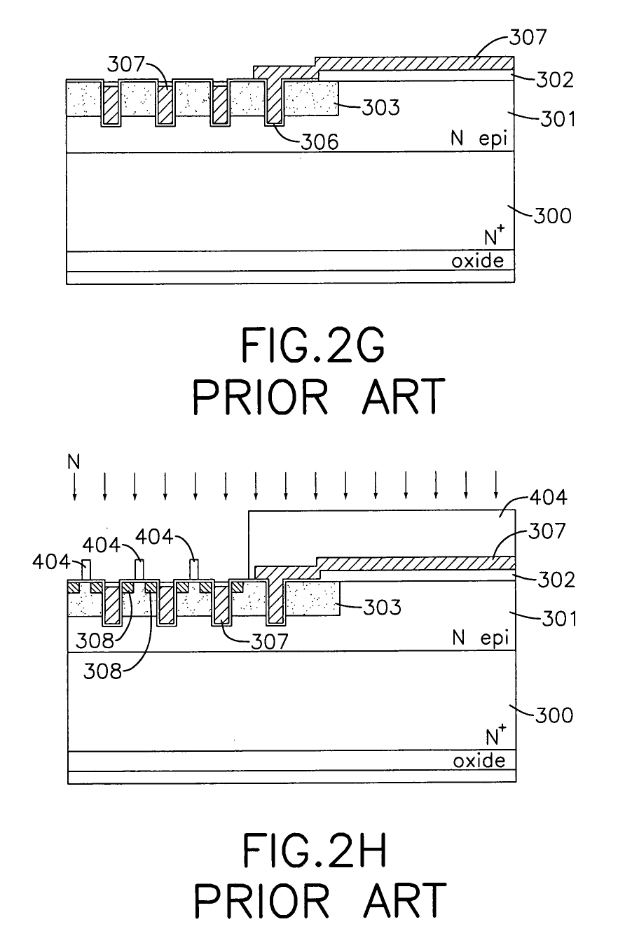

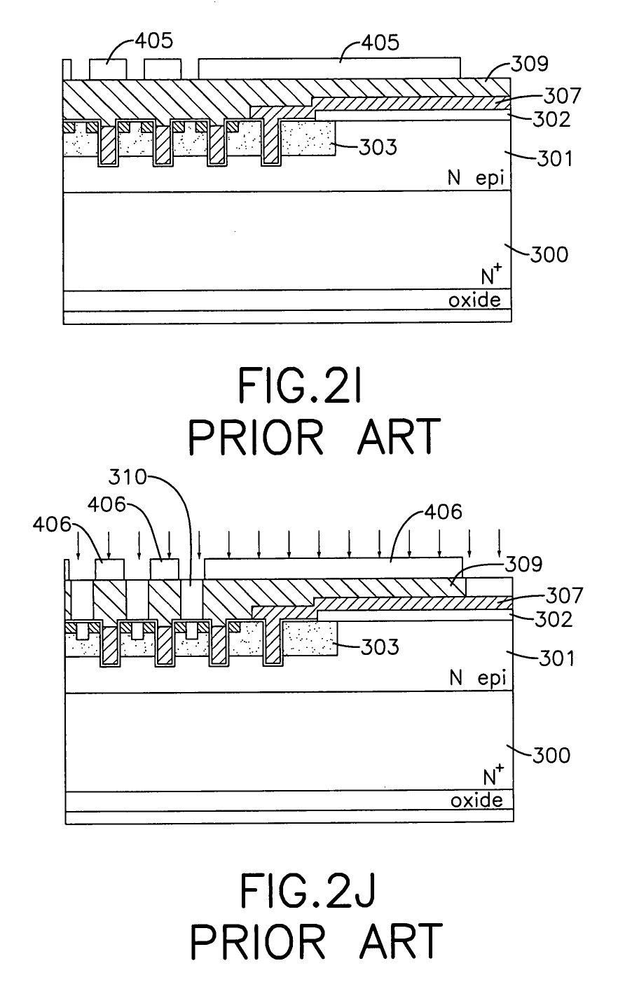

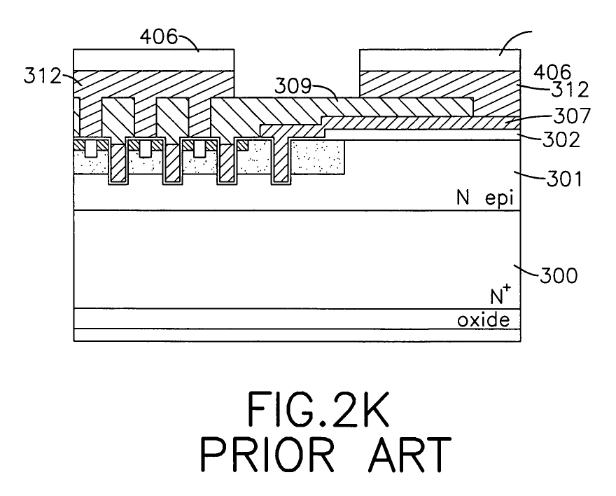

With reference to FIGS. 1A to 1H, the method for fabricating trench DMOS transistors and Schottky elements in accordance with the present invention uses only four masks to simplify processes and reduce the manufacturing cost.

With reference to FIG. 1A, an N-type epitaxial layer (101) is initially grown on a N+ substrate (100). A first oxide layer (102) is formed on the epitaxial layer (101) and a first photoresist layer (not shown) is then coated on the first oxide layer (102). A first mask (not shown), or named trench pattern mask, is used to define patterns of the first photoresist layer. Using the patterned first photoresist layer, the non-patterned portions of the first oxide layer (102) are etched to form multiple windows (103) at which the epitaxial layer (101) are exposed. After the etching process of the first oxide layer (102), the epitaxial layer (101) not covered by the oxide layer (102) is implanted and diffused to form P-body regions (104) through the windows (103). A second oxide layer is deposited on the first oxide layer (102), preferably by CVD process, and then etched back to form sidewall oxide spacers (105).

With reference to FIG. 1B, the P-body regions (104) are etched to form multiple trenches (106). Before forming a gate oxide layer, a sacrificial (SAC) oxide layer (not shown) is grown and etched off to remove damaged surfaces of the trenches (106) and simultaneously to smooth the trenches (106).

With reference to FIG. 1C, a polysilicon layer (108) is deposited by CVD process to fill the windows (103), the trenches (106) and cover the first oxide layer (102). The polysilicon layer (108) is etched back and only the polysilicon layer (106) in the trenches (106) is retained as the gate electrodes of the trench DMOS transistors.

With reference to FIG. 1D, the P-body region (104) is implanted with N-type semiconductor material to form N+ doped regions (109) as sources of the DMOS transistors. The N+ doped regions (109) are near the top surface of the P-body region (104) and abut to the gate oxide layer (107).

With reference to FIG. 1E, a passivation layer (110) such as borophosphosilicate glass (BPSG) is deposited by CVD on the first oxide layer (102) and fills the windows (103). A second photoresist layer (202) is coated on the passivation layer (110) and defined to form patterns by a second mask (not shown), i.e. a contact-hole pattern mask. Using the patterned second photoresist layer (202) as an etching mask, portions of the passivation layer (110) and the first oxide layer (102) are etched to form contact holes (111). After forming of the contact holes (111), the second photoresist layer (202) is removed.

With reference to FIG. 1F, a third photoresist layer (203) is coated on the epitaxial layer (101) and the passivation layer (110) and defied with patterns by using a third mask (not shown), or named a P+ contact pattern mask. Portions of the epitaxial layer (101) where not covered by the patterned third photoresist layer (203) are implanted through the contact holes (111) to form P+ contact regions (112) and guard ring regions (113) for the Schottky contact. After forming of the P+ contact regions (112) and P+ guard ring regions (113), the third photoresist layer (203) is removed.

With reference to FIG. 1G, a conductive layer (114) is formed on the passivation layer (110) and the epitaxial layer (101) by sputter process. Subsequently, a fourth photoresist layer (204) is coated on the conductive layer (114) and patterned by a fourth mask, or named conductive-wire pattern mask. Using the fourth photoresist layer (204) as the etching mask, portions of the conductive layer (114) are removed. With reference to FIG. 1H, the fourth photoresist layer (204) is removed from the conductive layer (113) to complete the forming of the trench DMOS transistors. The remaining conductive layer (114) covers the passivation layer (110) and fills the contact holes (111).

With reference to FIG. 1H, in addition to the forming of the trench DMOS transistor, the method in accordance with the present invention provides another feature. The junction between the conductive layer (114) and the epitaxial layer (101) forms a Schottky contact as a Schottky diode (120). A body diode (121) is formed by a p-n junction between the P-body region (104) and the N-type epitaxial layer (101). The forward voltage of the Schottky diode (120) is lower than the forward voltage of the body diode (121). Therefore, the Schottky diode (120) can be always turned on before the body diode (121) turns on. In comparison with the body diode (121) as a freewheeling element, the use of the Schottky diode (120) as a freewheeling element can reduce the switching losses.

According to the foregoing descriptions, the manufacturing method of the trench DMOS transistors in accordance with the present invention significantly reduces the number of masks to only four, i.e. the trench pattern mask, the contact-hole pattern mask, the P+ contact pattern mask and the conductive-wire pattern mask. Accordingly, the fabricating cost is decreased with the simplified processes.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A method for fabricating trench double diffused metal oxide semiconductor (DMOS) transistors and Schottky elements, the method comprising:
forming an epitaxial layer of a first type conductivity on a substrate of the first type conductivity;
forming a first oxide layer on the epitaxial layer;
defining trench patterns by using a first mask;
forming a body region of a second type conductivity within the epitaxial layer;
forming trenches through the body region based on the defined trench patterns;
growing a gate oxide layer for covering the body region;
filling the trenches with gate electrodes;
forming multiple doped regions of the first type conductivity within the body region between the trenches;
forming a passivation layer over the first oxide layer and covering the gate electrodes;
defining contact hole patterns by using a second mask;
forming contact holes through the passivation layer and the first oxide layer according to the defined contact hole patterns to expose portions of the body region;
defining contact region patterns by using a third mask;
forming contact regions of the second type conductivity within the exposed portions of the body region in the contact holes according to the defined contact region patterns;
defining conductive wire patterns by using a fourth mask; and
forming a conductive layer on the passivation layer, filling the contact holes and covering exposed portions of the epitaxial layer to form a Schottky contact at a junction between the conductive layer and the epitaxial layer.

2. The method as claimed in claim 1, wherein the first conductivity is an N type conductivity and the second conductivity is a P type conductivity.

3. The method as claimed in claim 1, the step of defining trench patterns further comprising:
coating a first photoresist layer on the first oxide layer; and
etching back the first oxide layer according to the defined trench patterns.

4. The method as claimed in claim 2, the step of defining trench patterns further comprising:
coating a first photoresist layer on the first oxide layer; and
etching back the first oxide layer according to the defined trench patterns.

5. The method as claimed in claim 2, after the forming of the body region, the method further comprising:
forming a second oxide layer on the first oxide layer and etching back to form sidewall oxide spacers abutting the first oxide layer.

6. The method as claimed in claim 2, the step of filling the trenches with gate electrodes further comprising:
depositing a polysilicon layer to fill the trenches and cover the first oxide layer; and
etching the polysilicon layer on the first oxide layer to retain the polysilicon layer within trenches as the gate electrodes.

7. The method as claimed in claim 1, wherein the first conductivity is a P type conductivity and the second conductivity is an N type conductivity.

8. The method as claimed in claim 7, the step of defining trench patterns further comprising:
coating a first photoresist layer on the first oxide layer; and
etching back the first oxide layer according to the defined trench patterns.

9. The method as claimed in claim 7, after the forming of the body region, the method further comprising:
forming a second oxide layer on the first oxide layer and etching back to form sidewall oxide spacers abutting the first oxide layer.

10. The method as claimed in claim 7, the step of filling the trenches with gate electrodes further comprising:
depositing a polysilicon layer to fill the trenches and cover the first oxide layer; and
etching the polysilicon layer on the first oxide layer to retain the polysilicon layer within trenches as the gate electrodes.
